(19) United States
(12) Patent Application Publication
(10) Pub. No.: US 2003/0054622 A1
(43) Pub. Date: Mar. 20, 2003

(54) Semiconductor device manufacturing method and semiconductor device

(76) Inventor: Ikuhiro Yamamura, Kanagawa (JP)

Correspondence Address: Ronald P Kananen, Rader Fishman & Grauer, Suite 501, 1233 20th Street NW, Washington, DC, 20036, US

(21) Appl. No.: 10/257,054

(22) PCT Filed: Feb. 6, 2002
(86) PCT No.: PCT/JP02/00975

(30) Foreign Application Priority Data
Feb. 13, 2001 (JP) 2001-35060

(51) Int. Cl. H01L 21/3205; H01L 21/4763; H01L 21/302; H01L 21/311; H01L 21/461

(52) U.S. Cl. 438/586; 438/637; 438/639; 438/640; 438/702; 438/705

(57) ABSTRACT

A method of fabricating a semiconductor device is advantageous in preventing occurrence of an erroneous short-circuit and a withstand voltage failure in a connection hole and preventing occurrence of a failure at the time of burying a connection hole with a metal. A silicon carbo-nitride film is formed on a conductor or an interconnection of a Damascene structure formed on a silicon substrate (S1), the silicon carbo-nitride film is taken as a side wall or an interlayer insulating film (S2), a silicon oxide film is formed on the silicon carbo-nitride film (S3), the upper side silicon oxide film is etched using the lower side silicon carbo-nitride film as an etching stopper layer (S4), and a connection hole is formed (S5).

### TECHNICAL FIELD

The present invention relates to a method of fabricating a semiconductor device, and particularly to a method of fabricating a semiconductor device, including a step of forming a connection hole.

### BACKGROUND ART

In recent years, to realize a higher degree of integration of a semiconductor device, there has been used a semiconductor device structure with no tolerance in interconnection between a connection hole and a diffusion layer of a transistor connected in the connection hole and interconnection between the connection hole and an interconnection layer.

To realize the above device structure, there is generally used a method of stacking insulating films to each other as an insulating film in which a connection hole is to be formed, and forming a connection hole by selectively etching one of the insulating films against the other, thereby preventing occurrence of an erroneous short-circuit and a withstand voltage failure between a metal buried in the connection hole and a conductive portion such as a gate electrode or a bit line.

As the method of selectively etching one of insulating films stacked to each other, there has been known a method of stacking a silicon oxide film and a silicon nitride film to each other, and forming a connection hole under an etching condition that the silicon oxide film is selectively etched against the silicon nitride film.

The above-described method of stacking the silicon oxide film and the silicon nitride film to each other and forming a connection hole by selectively etching the silicon oxide film against the silicon nitride film has a problem that since the silicon oxide film cannot be etched with a high selection ratio against the silicon nitride film, the silicon nitride film is liable to be etched upon etching of the silicon oxide film, to cause an erroneous short-circuit and a withstand voltage failure in a connection hole.

As one example, a method of forming a connection hole to a depth reaching a diffusion layer of a transistor, will be described below.

FIG. 5 is a schematic sectional view of a semiconductor device.

The semiconductor device shown in FIG. 5 includes a stacked structure formed on a silicon substrate 11. The stacked structure includes a device-isolation film 12 for preventing an electric parasitic effect between devices, a gate insulating film 13 for a transistor, a gate electrode 14 for the transistor, a silicon nitride film 15a as an etching resist for the gate electrode 14, a silicon nitride film 15b as a side wall of the gate electrode 14, a diffusion layer 17 for the transistor, a cobalt silicide 18 formed on the diffusion layer 17, a silicon oxide film 19 formed on the upper side transistor, a pattern resist 110 for a connection hole, and a connection hole 111 formed to a depth reaching the cobalt silicide 18.

The connection hole 111 is formed by selectively, anisotropically etching the silicon oxide film 19 against the side wall composed of the silicon nitride film 15b with the use of the pattern resist 110. However, in this case, since the silicon oxide film 19 cannot be etched with a high selection ratio against the silicon nitride film 15b, the silicon nitride film 15b is etched. As a result, the film thickness of the silicon nitride film 15b as an insulating film between the connection hole ill and the gate electrode 14 becomes thin, to cause an erroneous short-circuit and a withstand voltage failure.

As another example, a method of fabricating multilayer interconnections using a Damascene process, will be described below.

FIG. 6 is a schematic sectional view showing an interconnection portion of a Damascene structure.

The semiconductor device shown in FIG. 6 includes a silicon oxide film 31, a silicon oxide film 32 for isolating copper interconnections from each other, a copper interconnection 33 formed by a Damascene process, a silicon nitride film 39 functioning as both a copper diffusion preventing layer and an etching stopper layer, an upper side silicon oxide film 35, a pattern resist 36 for a connection hole pattern, and a connection hole 37.

The connection hole 37 shown in FIG. 6 is formed by selectively, anisotropically etching the silicon oxide film 35 against the silicon nitride film 39 with the use of the pattern resist 36 and then etching the silicon nitride film 39. However, in this case, since the silicon nitride film 35 cannot be etched with a high selection ratio against the silicon nitride film 39, the silicon oxide film 32 in which the copper interconnection 33 has been formed is etched, to form a cavity 38 adjacently to the copper interconnection 33, thereby causing a failure that the connection hole 37 is sufficiently buried with a metal, that is, the cavity 38 adjacent to the copper interconnection 33 is not buried with a metal.

In this way, in the method of stacking the silicon oxide film and the silicon nitride film to each other, and forming a connection hole by selectively etching the silicon oxide film, it fails to sufficiently ensure the selection ratio of the silicon oxide film against the silicon nitride film. Therefore, there is a possibility that the silicon nitride film be etched upon etching of the silicon oxide film. As a result, there arise problems associated with occurrence of an erroneous short-circuit and a withstand voltage failure in a connection hole, and also occurrence of a failure in burying a connection hole with a metal upon formation of an interconnection.

In view of the foregoing, the present invention has been made, and an object of the present invention is to provide a method of fabricating a semiconductor device, which is capable of preventing occurrence of an erroneous short-circuit and a withstand voltage failure in a connection hole.

Another object of the present invention is to provide a method of fabricating a semiconductor device, which is capable of preventing occurrence of a failure in burying a connection hole with a metal upon formation of an interconnection.

### DISCLOSURE OF INVENTION

According to the present invention, there is provided a method of fabricating a semiconductor device, including a step of forming a connection hole by etching a silicon oxide film, the method including the steps of: forming a conductor on a silicon substrate; forming a silicon carbo-nitride film on the silicon substrate and the conductor; forming a side wall by etching the silicon carbo-nitride film; forming a silicon oxide film; and forming a connection hole by etching the silicon oxide film with the silicon carbo-nitride film used as an etching stopper layer.

With this configuration, a silicon carbo-nitride film is formed as a side wall on a conductor such as a gate electrode or a bit line and is used as an etching stopper layer. Accordingly, at the time of forming a silicon oxide film on the silicon carbo-nitride film and forming a connection hole by etching the silicon oxide film, the silicon carbo-nitride film is sufficiently remains. As a result, it is possible to prevent occurrence of an erroneous short-circuit and a withstand voltage failure due to the lack of film thickness of the side wall.

According to the present invention, there is also provided a method of fabricating a semiconductor device, including a step of forming a connection hole by etching a silicon oxide film, the method including the steps of: forming a groove in an insulating film and forming a copper interconnection in the groove; forming a silicon carbo-nitride film on the insulating film and the copper interconnection; forming a silicon oxide film on the silicon carbo-nitride film; and forming a connection hole by etching the silicon oxide film with the silicon carbo-nitride film used as an etching stopper layer.

With this configuration, a groove is formed in an insulating film and a copper interconnection is formed in the groove, and then a silicon carbo-nitride film is formed as an etching stopper film on the insulating film and the copper interconnection. Accordingly, at the time of forming a silicon oxide film on the silicon carbo-nitride film and forming a connection hole by etching the silicon oxide film, the silicon carbo-nitride film sufficiently remains. As a result, the etching does not proceed up to the insulating film in which the copper interconnection has been formed, to thereby prevent occurrence of a failure at the time of burying the connection hole with a metal.

### BRIEF DESCRIPTION OF DRAWINGS

FIG. 1 is a flow chart schematically showing a process of forming a connection hole according to the mode for carrying out the invention;

FIGS. 2A to 2D are schematic sectional views of a semiconductor according to one embodiment to which the mode for carrying out the invention is applied;

FIG. 3 is a schematic view of a semiconductor device in a process of fabricating a DRAM according to another embodiment to which the mode for carrying out the invention is applied;

FIGS. 4A to 4C are schematic sectional views showing an interconnection portion of a Damascene structure according to a further embodiment to which the mode for carrying out the invention is applied:

FIG. 5 is a schematic sectional view of a semiconductor device; and

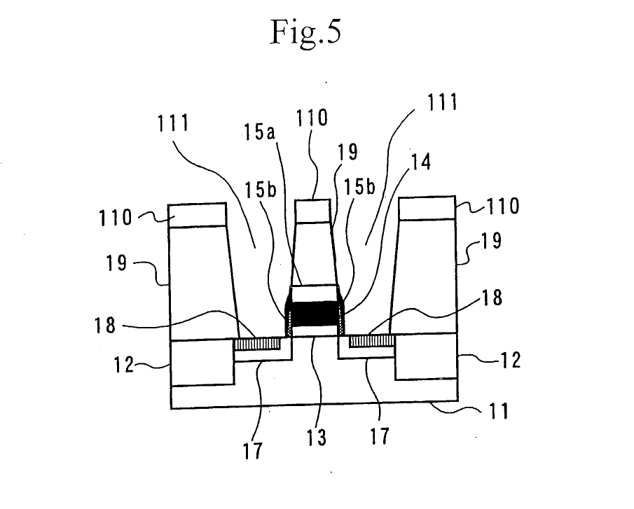

FIG. 6 is a schematic sectional view showing an interconnection portion of a Damascene structure.

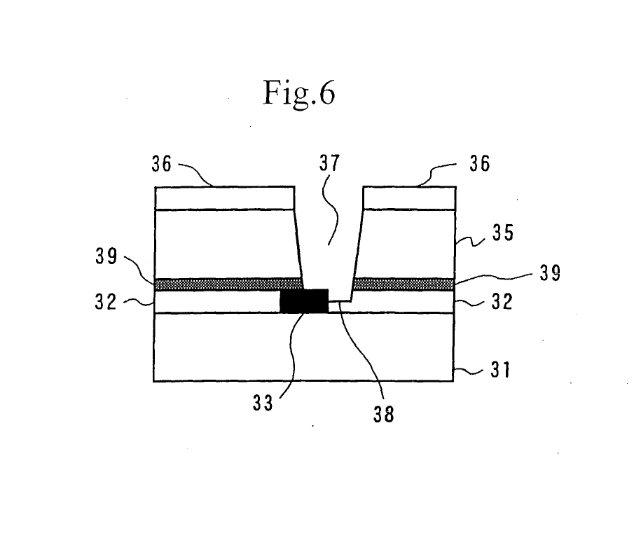

### BEST MODE FOR CARRYING OUT THE INVENTION

Hereinafter, the mode for carrying out the invention will be described with reference to the drawings.

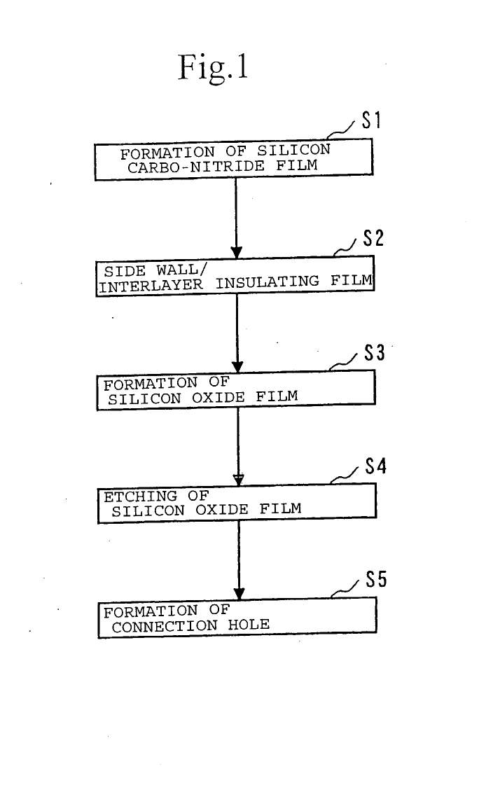

FIG. 1 is a flow chart schematically showing a process of forming a connection hole according to the mode for carrying out the invention.

A silicon carbo-nitride film is formed on a conductor or an interconnection of a Damascene structure formed on a silicon substrate (S1), the silicon carbo-nitride film is taken as a side wall or an interlayer insulating film (S2), a silicon oxide film is formed on the upper side silicon carbo-nitride film (S3), the upper side silicon oxide film is etched using the lower side silicon carbo-nitride film as an etching stopper layer (S4), and a connection hole is formed (S5).

One embodiment, to which the mode for carrying out the invention is applied to a method of connecting a connection hole to a depth reaching a diffusion layer of a transistor, will be described below.

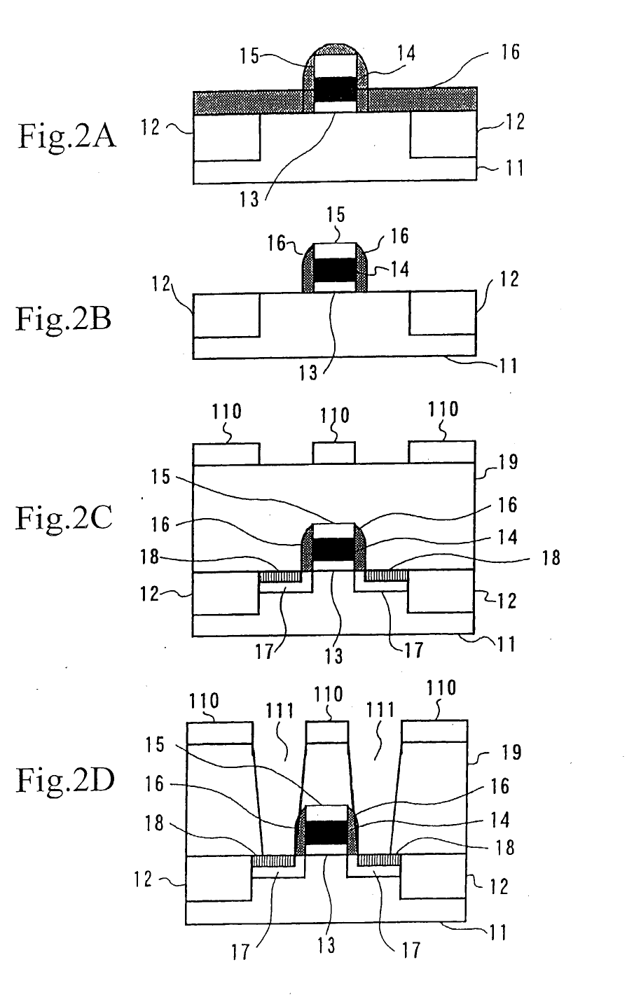

FIGS. 2A to 2D are schematic sectional views of a semiconductor device, wherein FIG. 2A shows a step of forming a silicon carbo-nitride film, FIG. 2B shows a step of etching the silicon carbo-nitride film, FIG. 2C shows a step of forming a silicon oxide film and then forming a connection hole pattern, and FIG. 2D shows a step of forming a connection hole.

The semiconductor device shown in FIGS. 2A to 2D includes a stacked structure formed on a silicon substrate 11. The stacked structure includes a device-isolation film 12 for preventing an electric parasitic effect between devices, a gate insulating film 13 for a transistor, a gate electrode 14 for the transistor, a silicon nitride film 15 as an etching resist of the gate electrode 14, a silicon carbo-nitride film 16 as a side wall of the gate electrode 14, a diffusion layer 17 for the upper side transistor, a cobalt silicide 18 formed on the diffusion layer 17, a silicon oxide film 19 formed on the transistor, a pattern resist 110 for a connection hole, and a connection hole 111 formed to a depth reaching the cobalt silicide 18.

In the step shown in FIG. 2A, a device isolation film 12 is formed on a silicon substrate 11; a gate for a transistor, composed of a gate insulating film 13, a gate electrode 14, and a silicon nitride film 15, is formed; and a silicon carbo-nitride film 16 is formed.

The formation of the silicon carbo-nitride film 16 is performed by forming a silicon nitride film using N₂, NH₃, and SiCl₂H₂ by a low pressure CVD (LP-CVD) process, and implanting carbon in the silicon nitride film by an ion-implantation process, to thereby form the silicon carbo-nitride film 16. Alternatively, the silicon carbo-nitride film 16 may be directly formed by a CVD process.

In the step shown in FIG. 2B, the silicon carbo-nitride film 16 is anisotropically etched in such a manner as to form a side wall structure in which the silicon carbo-nitride film 16 remains only on a side wall of the gate electrode 14. The silicon carbo-nitride film 16 may be anisotropically etched in such a manner as to form a structure in which the silicon carbo-nitride film 16 remains on a side wall of the gate electrode 14 and on the device-isolation film 12. Even with this structure, the same effect can be obtained.

In the step shown in FIG. 2C, a diffusion layer 17 and a cobalt silicide 18 are formed, and a silicon oxide film 19 is formed thereon. The silicon oxide film 19 is then planarized by a CMP (Chemical-Mechanical Polishing) process, and a pattern of a connection hole 111 is formed on the silicon oxide film 19 using a pattern resist 110 by photolithography.

In the step shown in FIG. 2D, the silicon oxide film 19 is anisotropically etched using the pattern resist 110 as a mask to a depth reaching the cobalt silicide 18, to form a connection hole 111.

In the formation of the connection hole 111, the etching of the silicon oxide film 19 using the pattern resist 110 as a mask may be performed by a magnetron reactive ion etching using C₅F₈, O₂, and Ar gases.

In this case, over-etching is required to compensate for a variation in film thickness of the silicon oxide film 19 and a variation in etching. However, since the silicon oxide film 19 is etched at a high selection ratio against the silicon carbo-nitride film 16, the silicon carbo-nitride film 16 is little etched. As a result, the silicon carbo-nitride film 16 forming the side wall sufficiently remains upon etching of the silicon oxide film 19. Therefore, the silicon oxide film 19 can be over-etched without occurrence of the lack of film thickness of the silicon carbo-nitride film 16 as the insulating film between the connection hole 111 and the gate electrode 14, thereby preventing occurrence of an erroneous short-circuit and a withstand voltage failure due to the lack of the film thickness of the silicon carbo-nitride film 16.

In the above description, the silicon nitride film 15 can be replaced with the silicon carbo-nitride film 16, and in this case, if the connection hole 111 is present over the gate electrode 14, since the silicon oxide film 19 can be etched without occurrence of the lack of film thickness of the silicon carbo-nitride film 16, it is possible to prevent occurrence of an erroneous short-circuit and a withstand voltage failure between the connection hole 111 and the gate electrode 14.

Another embodiment, in which the mode for carrying out the invention is applied to a fabrication of a DRAM (Dynamic Random Access Memory), will be described below.

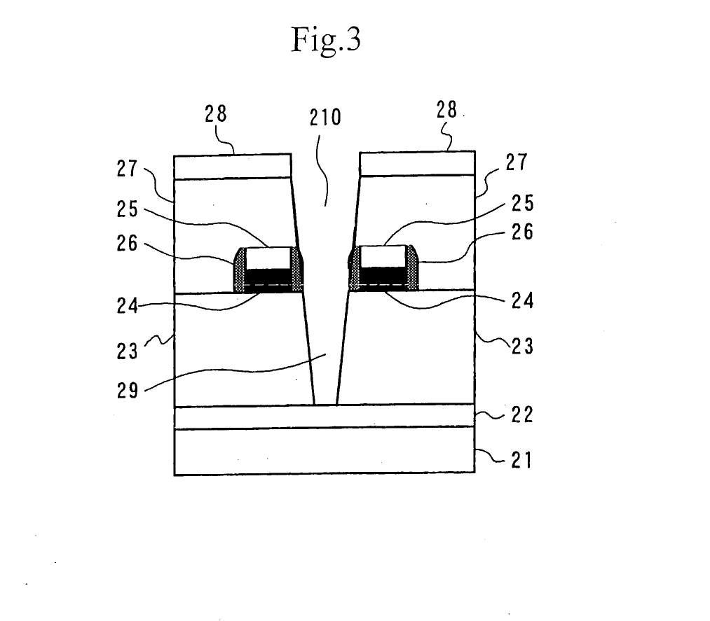

FIG. 3 is a schematic sectional view of a semiconductor device in a process of fabricating a DRAM.

The semiconductor device shown in FIG. 3 includes a stacked structure formed on a silicon substrate 21. The stacked structure includes a diffusion layer 22, a silicon oxide film 23 as an insulating film between the diffusion layer 22 and a bit line, a bit line 24, a silicon nitride film 25 as an etching resist for the bit line 24, a silicon carbo-nitride film 26 as a side wall of the bit line 24, a silicon oxide film 27 formed on the bit line 24, a pattern resist 28 for a connection hole, and a connection hole 29 and a connection hole 210 for connecting the diffusion layer 22 to a capacitor to be formed on the bit line 24.

In the formation of the connection holes 29 and 210 for connecting the diffusion layer 22 on the silicon substrate 21 to the capacitor required for a structure provided with the capacitor on the bit line 24, since the side wall composed of the silicon carbo-nitride film 26 is formed around the bit line 24, it is possible to prevent occurrence of an erroneous short-circuit and a withstand voltage failure between the connection holes 29 and 210 and the bit line 24.

As described above, since the side walls of the gate electrode 14 and the bit line 24 are formed by the silicon carbo-nitride films 16 and 26 respectively, the silicon oxide films 19, 23, and 27 for forming the connection holes 111, 29, and 210 respectively can be etched without occurrence of the lack of film thickness of the silicon carbo-nitride films 16 and 26 as the side walls, thereby preventing occurrence of erroneous short-circuits and withstand voltage failures due to the lack of the film thickness of the silicon carbo-nitride films 16 and 26.

A further embodiment, in which the mode for carrying out the invention is applied to a method of fabrication of multi-layer interconnections using a Damascene process, will be described below.

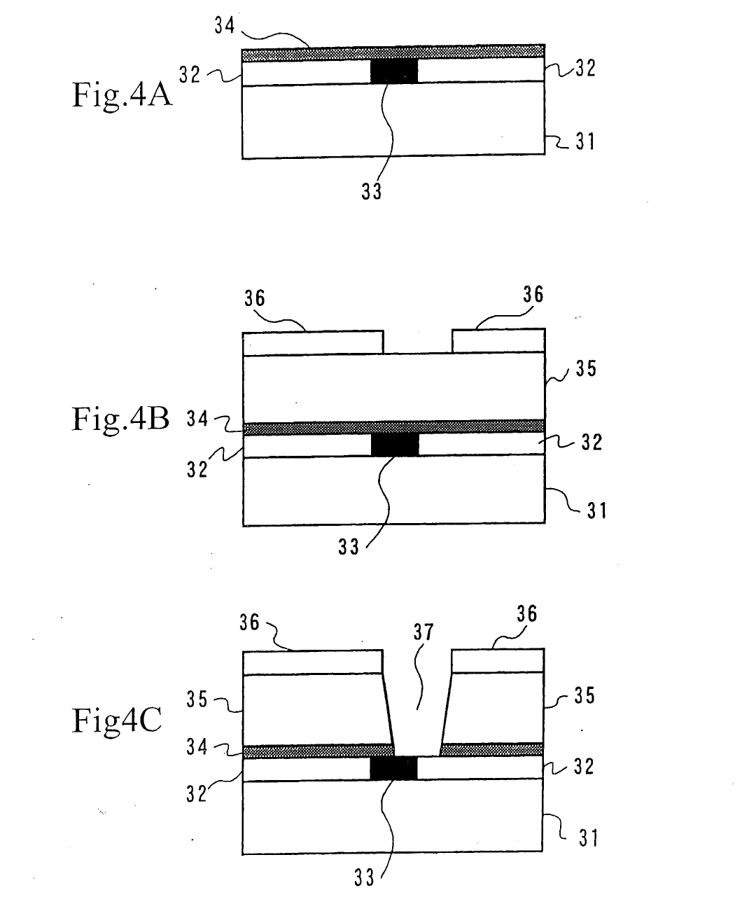

FIGS. 4A to 4C are schematic sectional views of an interconnection portion of a Damascene structure, wherein FIG. 4A shows a step of forming a silicon carbo-nitride film on a copper interconnection, FIG. 4B shows a step of forming a silicon oxide film and then forming a connection hole pattern, and FIG. 4C shows a step of forming a connection hole.

The semiconductor device shown in FIGS. 4A to 4C includes a silicon oxide film 31, a silicon oxide film 32 for isolating copper interconnections from each other, a copper interconnection 33 having a Damascene structure, a silicon carbo-nitride film 34 as both a copper diffusion preventing layer and an etching stopper layer, a silicon oxide film 35 on the upper side silicon carbo-nitride film 34, a pattern resist 36 for a connection hole pattern, and a connection hole 37.

In the step shown in FIG. 4A, a silicon oxide film 32 is formed on an underlying silicon oxide film 31 and a copper interconnection 33 is formed by the Damascene process, and then a silicon carbo-nitride film 34 is formed. The formation of the silicon carbo-nitride film 34 is performed by using N₂, NH₃, and SiH(CH₃)₃ gases by a plasma CVD process. The silicon carbo-nitride film 34 may be formed by forming a silicon nitride film using N₂, NH₃, and SiCl₂H₂ by a low pressure CVD (LP-CVD) process, and carbon is implanted in the silicon nitride film by an ion-implantation process. Alternatively, the silicon carbo-nitride film 34 may be directly formed by a CVD process.

The silicon carbo-nitride film 34 functions not only as an etching stopper layer but also as a diffusion preventing layer for preventing a withstand voltage failure due to diffusion of copper from the copper interconnection 33 into a silicon oxide film 35.

In the step shown in FIG. 4B, a silicon oxide film 35 is formed on the upper side silicon carbo-nitride film 34, and a pattern of a connection hole 37 is formed using a pattern resist 36 by photolithography.

In the step shown in FIG. 4C, the silicon oxide film 35 is anisotropically etched using the pattern resist 36 to a depth reaching the silicon carbo-nitride film 34. Over-etching is required to compensate for a variation in film thickness of the silicon oxide film 35 and a variation in etching of the silicon oxide film 35. However, since the silicon carbo-nitride film 34 is less etched, the etching does not proceed up to the silicon oxide film 32, thereby preventing occurrence of a failure at the time of burying a connection hole 37 with a metal.

The silicon carbo-nitride film 34 is then etched, to form a connection hole 37. The etching of the silicon carbo-nitride film 34 is typically performed by using CHF₃, O₂, and Ar gases by a magnetron reactive ion etching process.

As described above, in fabrication of multi-layer interconnections by the Damascene process, after the copper interconnection 33 of the Damascene structure is formed, the silicon carbo-nitride film 34 is formed. The silicon carbo-nitride film 34 functions as the etching stopper layer upon formation of the connection hole 37. Consequently, upon etching of the silicon oxide film 35, the etching does not proceed up to the silicon oxide film 32. This is advantageous in preventing occurrence of a failure at the time of burying the connection hole 37 with a metal. The silicon carbo-nitride film 34 also functions as a diffusion preventing layer for preventing occurrence of a withstand voltage failure due to diffusion of copper in the silicon oxide film 35.

The silicon carbo-nitride film 34 may be used as an interlayer insulating film.

Additionally, in formation of a multi-layer interconnection structure using the Damascene process, all of interconnection layers may be formed by the silicon carbo-nitride films 34. In this case, a connection hole can be accurately formed in each interconnection layer.

As described above, according to the present invention, since a side wall is formed by a silicon carbo-nitride film and a connection hole is formed using the silicon carbo-nitride film as an etching stopper layer, it is possible to form the connection hole without the lack of film thickness of the side wall, and hence to prevent occurrence of an erroneous short-circuit and a withstand voltage failure between the connection hole and a gate electrode or an interconnection.

Also, since an insulating film in which an interconnection of a Damascene structure has been formed is formed and a silicon carbo-nitride film is formed thereon and then a connection hole is formed using the silicon carbo-nitride film as an etching stopper layer, it is possible to prevent occurrence of a failure at the time of burying the connection hole with a metal. The silicon carbo-nitride film can be used as a diffusion preventing layer for preventing diffusion of copper from the copper interconnection.

As a result, according to the present invention, it is possible to enhance the degree of integration of a semiconductor device and hence to fabricate a semiconductor device with a high quality and a high reliability.

1. A method of fabricating a semiconductor device, including a step of forming a connection hole by etching a silicon oxide film, said method comprising the steps of:
forming a conductor on a silicon substrate;
forming a silicon carbo-nitride film on said silicon substrate and said conductor;
forming a side wall by etching said silicon carbo-nitride film;
forming a silicon oxide film; and
forming a connection hole by etching said silicon oxide film with said silicon carbo-nitride film used as an etching stopper layer.

2. A method of fabricating a semiconductor device according to claim 1, wherein said conductor is a gate electrode.

3. A method of fabricating a semiconductor device according to claim 1, wherein said conductor is a bit line.

4. A semiconductor device fabricated by said method of fabricating a semiconductor device according to claim 1.

5. A method of fabricating a semiconductor device, including a step of forming a connection hole by etching a silicon oxide film, said method comprising the steps of:
forming a groove in an insulating film and forming a copper interconnection in said groove;
forming a silicon carbo-nitride film on said insulating film and said copper interconnection;
forming a silicon oxide film on said silicon carbo-nitride film; and
forming a connection hole by etching said silicon oxide film with said silicon carbo-nitride film used as an etching stopper layer.

6. A method of fabricating a semiconductor device according to claim 5, wherein said silicon carbo-nitride film functions as a diffusion preventing layer for preventing diffusion of copper from said copper interconnection.

7. A method of fabricating a semiconductor device according to claim 5, wherein said silicon carbo-nitride film functions as an interlayer insulating layer.

8. A semiconductor device fabricated by said method of fabricating a semiconductor device according to claim 5.
